(19) United States
(12) Patent Application Publication
(10) Pub. No.: US 2022/0224278 A1
(43) Pub. Date: Jul. 14, 2022

(54) SOLAR POWER SYSTEM FOR VEHICLES

(71) Applicant: Albert Vernon Wright, Surprise, AZ (US)

(72) Inventor: Albert Vernon Wright, Surprise, AZ (US)

(21) Appl. No.: 17/595,475

(22) PCT Filed: May 20, 2020
(86) PCT No.: PCT/US2020/033840

§ 371 Date: Nov. 17, 2021

Related U.S. Application Data
(60) Provisional application No. 62/852,061, filed on May 23, 2019.

(51) Int. Cl. H02S 10/40; H01L 31/048; H01L 31/056; H01L 31/18; B62D 33/04; B60H 1/00

(52) U.S. Cl. CPC H02S 10/40; H01L 31/048; B60H 1/00428; H01L 31/18; B62D 33/048; H01L 31/056

(57) ABSTRACT

Systems and methods directed to a solar electric system for use in freight systems. In some embodiments, a solar power system can be configured to provide power to a refrigerated truck trailer. For example, a solar power system can be composed of a solar panel package that can include solar cell layer(s), conductive material(s), and support portion(s).

### CROSS-REFERENCE TO RELATED APPLICATIONS

This application claims the benefit of priority to U.S. Provisional Patent Application No. 62/852,061, filed May 23, 2019, entitled “SOLAR POWER SYSTEM FOR SEMI-TRAILERS”, which is hereby incorporated by reference herein in its entirety.

### FIELD

The systems and methods disclosed herein are directed to solar electric panels for use in transportation systems.

### BACKGROUND

Billions of dollars of goods are transported every year through freight shipments using ships, trains, and trucks. Perishable goods, in particular, often have specialized transport needs, such as refrigeration requirements. Refrigerated transport generally requires temperature controlled or refrigerated vehicles, containers, or trailers. To maintain temperature control, these containers can have a constant source of power during shipment.

### SUMMARY

Certain aspects, advantages, and novel features of the present disclosure are described herein. It is to be understood that not necessarily all such advantages can be achieved in accordance with any particular embodiment of the present disclosure. Thus, the features, aspects, and advantages of the present disclosure can be embodied or carried out in a manner that achieves or selects one advantage or group of advantages as taught herein without necessarily achieving other advantages as can be taught or suggested herein.

A solar power system for use with automotive vehicles can include: at least one solar panel package disposed on a vehicle surface, the solar panel package can adhere to a vehicle surface by an adhesive material, wherein the at least one solar panel package includes: a support layer that includes a shock absorption layer that can reduce vibration from vertical movements of the vehicle surface; a conductive layer disposed on the support layer, said conductive layer can provide rigidity to the at least one solar panel package; and a solar cell layer disposed above the conductive layer, said solar cell layer can capture photons and convert into electricity, wherein the conductive layer can reflect photons that passed through the solar cell layer, thereby not initially captured, back into the solar cell layer; and an encapsulating layer that can cover at least the solar cell layer, the encapsulating layer can include a material that can allow transmission of light and protect the solar cell layer from impact damage.

The at least one solar panel package can include between one and twenty four or more solar panel packages. The at least one solar power package can cover an area of the vehicle surface sufficient to supply power for a refrigeration unit associated with the vehicle or other electrical appliances.

The adhesive material can include a bonding adhesive.

The support layer can include a fiberglass material.

The shock absorption layer can include foam core. The shock absorption layer can include a honeycomb shaped material.

The conductive layer can include a carbon fiber material impregnated with resin.

The encapsulating layer can include a transparent laminate. The encapsulating can include an ink layer that can hide electrical components of the solar cell layer.

A method of configuring an automotive vehicle to include a solar power system can include: providing an adhesive layer to a vehicle surface; providing at least one solar panel package to the vehicle surface, said at least one solar panel package can include: a support layer that can include a shock absorption layer that can reduce vibration from vertical movements of the vehicle surface; a conductive layer disposed on the support layer, said conductive layer that can provide rigidity to the at least one solar panel package; and a solar cell layer disposed above the conductive layer, said solar cell layer that can capture photons and convert into electricity, wherein the conductive layer can reflect photons that passed through the solar cell layer, thereby not initially captured, back into the solar cell layer; and applying an encapsulating layer that can cover at least the solar cell layer, the encapsulating layer can include a material that can allow transmission of light and protect the solar cell layer from impact damage.

The adhesive layer can include an adhesive material. The adhesive material can include a bonding adhesive.

The shock absorbing layer can include a shock absorption material. The shock absorption material can include foam core. The shock absorption layer can include a honeycomb shaped structure.

The method can include electrically connecting the solar panel package to electronic components associated with the vehicle. The method can include electrically connecting the solar panel package to electronic components associated with the refrigeration system.

A method of manufacturing a solar panel package can include: providing a shock absorption layer to a reinforcement material; providing a conductive material to the shock absorption layer; and providing a solar cell layer to the conductive material.

The conductive material can reflect photons that passed through the solar cell layer, thereby not initially captured, bounced back into the solar cell layer. The conductive material is configured to provide rigidity to the at least one solar panel package.

A method of disposing a solar power system on a truck trailer can include: providing an adhesive layer to a first surface of the truck trailer; providing at least one solar panel package to the surface of the truck trailer, wherein the adhesive layer is disposed between the surface and the solar panel package; providing an encapsulating layer over the solar panel package, the encapsulating layer comprising a material configured to allow transmission of light and protect the solar cell layer from impact damage; attaching one or more power control components to a second surface of the truck trailer behind a weather resistant barrier; and electrically connecting the one or more power control components to the at least one solar panel package, a power supply associated with the truck trailer, a display, external power supply, or a battery system configured to store power produced by the solar panel package. Electrically connecting the one or more power control components can include: laying one or more power cables along one or more surfaces of the trailer; feeding the one or more power cables through an electrical feed through connector associated with the weather resistant barrier; and connecting the one or more power cables with the at least one solar panel package, a power supply associated with the truck trailer, a display, an external power supply, or a battery system configured to store power produced by the solar panel package. The at least one solar panel package can include: a support layer comprising a shock absorption layer configured to reduce vibration from vertical movements of the vehicle surface; a reinforcing layer disposed on the support layer, said reinforcing layer configured to provide rigidity to the at least one solar panel package; and a solar cell layer disposed above the reinforcing layer, said solar cell layer can be configured to capture photons and convert into electricity.

A method of disposing a solar power system on a truck trailer can include: calculating a power need for the truck trailer; calculating a threshold surface area to meet the power need; determining an suitable surface area for one or more solar panel packages on the truck trailer; applying the one or more solar panel packages on the truck trailer; attaching one or more movable panels comprising one or more additional solar panel packages to the truck trailer if the suitable surface area is less than the threshold surface area; attaching one or more power control components to a surface of the truck trailer behind a weather resistant barrier; and electrically connecting the one or more power control components to at least one of the one or more solar panel packages, a power supply associated with the truck trailer, a display, an external power supply, or a battery system configured to store power. Electrically connecting the one or more power control components can include: laying one or more power cables along one or more surfaces of the trailer; feeding the one or more power cables through an electrical feed through connector associated with the weather resistant barrier; and connecting the one or more power cables with at least one of the one or more solar panel packages, a power supply associated with the truck trailer, a display, external power supply, or a battery system configured to store power produced by the solar panel package. The one or more solar panel packages can include: a support layer comprising a shock absorption layer configured to reduce vibration from vertical movements of the vehicle surface; a reinforcing layer disposed on the support layer, said reinforcing layer configured to provide rigidity to the at least one solar panel package; and a solar cell layer disposed above the reinforcing layer, said solar cell layer configured to capture photons and convert into electricity.

A solar power system can include: at least one solar panel package; a first securing portion disposed onto a vertical surface of the trailer, the first support portion configured to secure at least a portion of the solar panel package during transit of the trailer; at least one hinge configured to allow the at least one solar panel package to pivot around an axis of the solar panel package; and a moving component configured to orient the at least one solar panel package into a position associated with improved sun exposure. The at least one solar panel package can include: a support layer comprising a shock absorption layer configured to reduce vibration from vertical movements of the vehicle surface; a reinforcing layer disposed on the support layer, said reinforcing layer configured to provide rigidity to the at least one solar panel package; and a solar cell layer disposed above the reinforcing layer, said solar cell layer configured to capture photons and convert into electricity.

### BRIEF DESCRIPTION OF THE DRAWINGS

FIG. 1A illustrates a side view of an embodiment of a solar power system equipped on a truck trailer.

FIG. 1B-1 illustrates a top down view of an embodiment of the solar power system illustrated in FIG. 1A.

FIG. 1B-2 illustrates a top down view of another embodiment of a solar power system.

FIG. 1C-1 illustrates a front view of an embodiment of the solar power system illustrated in FIG. 1A.

FIG. 1C-2 illustrate a front view of another embodiment of a solar power system.

FIG. 1D illustrates external views of an example trailer that may be provided with a solar power system.

FIG. 1E illustrates views of an example electrical setup that may be associated with a solar panel system.

FIG. 1F illustrates internal views of an example trailer that may be provided with a solar power system.

FIG. 2A illustrates a block diagram of an example solar power system coupled to a trailer surface.

FIG. 2B illustrates an example process of providing a truck trailer with a solar power system.

FIGS. 3A and 3B show block diagrams of example solar panel packages in an embodiment of a solar power system.

FIG. 4 illustrates example support portion panels that may be part of a solar power system.

FIG. 5A illustrates an example solar panel package that can be part of a solar power system.

FIG. 5B illustrates example variants of a solar panel package that may be part of a solar power system.

FIG. 6 illustrates example panel test values that may be associated with the example variants shown in FIG. 5B.

### DETAILED DESCRIPTION

Many refrigerated containers are fitted with or coupled to a generator, such as a diesel generator, in order to provide power. However, diesel generators are a source of carbon exhaust pollution and must be periodically refueled. The refueling process can take time and inconvenience a truck driver during shipment. Thus, what is needed is an efficient, clean power source for a refrigerated container.

The present disclosure provides systems and methods for providing power to refrigerated systems without requiring regular refueling. In particular, the present disclosure provides a solar power system for use in transport vehicles, containers, and trailers. A solar power system does not require refueling in order to generate electricity because it draws its energy source from solar radiation. Transport vehicles, containers, and trailers can spend large amounts of time exposed to solar radiation during the transport. Thus, providing a transport vehicle, container, or trailer with a solar power system capable of powering a refrigerated vehicle, container, or trailer can be beneficial for the efficient transportation of refrigerated goods.

### I. Overview

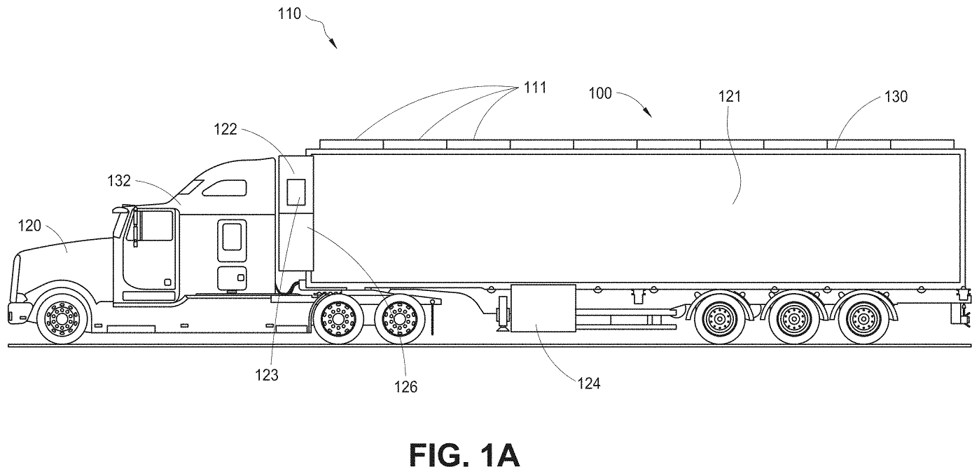

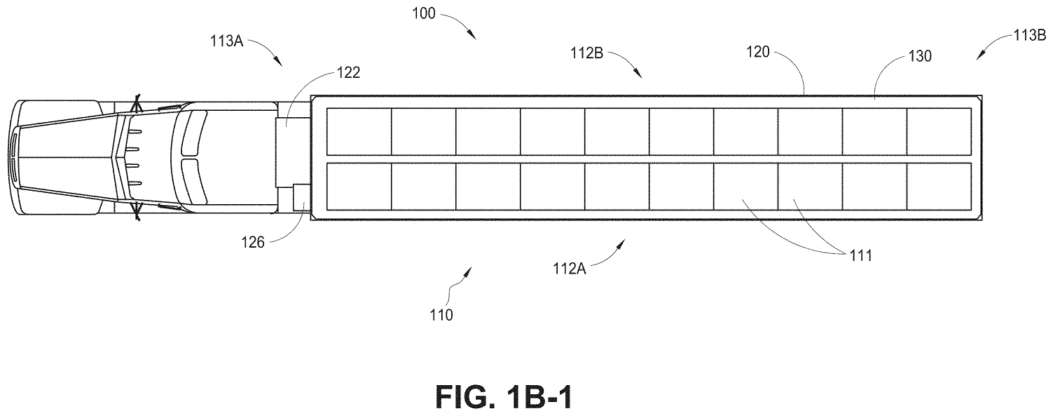

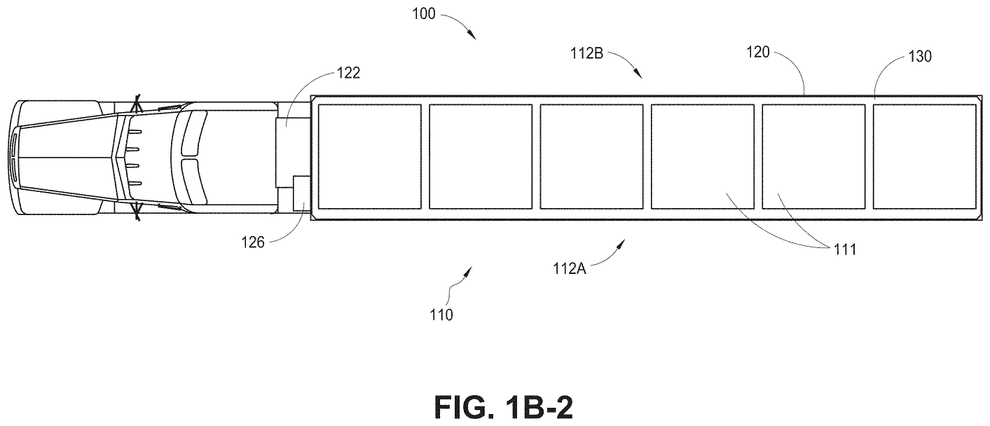

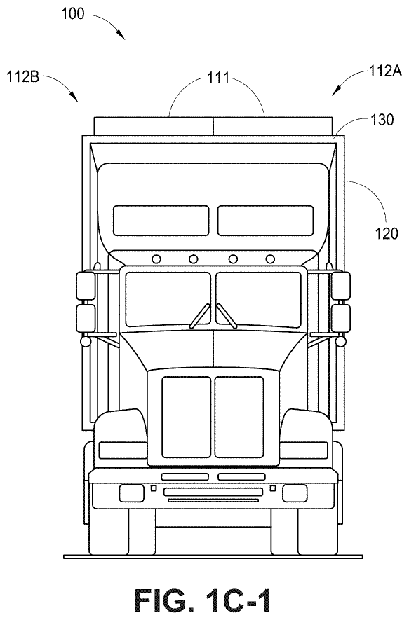

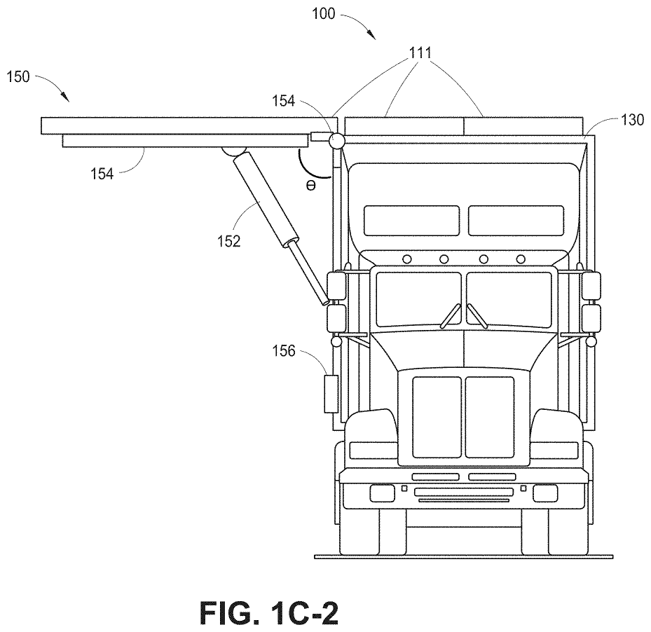

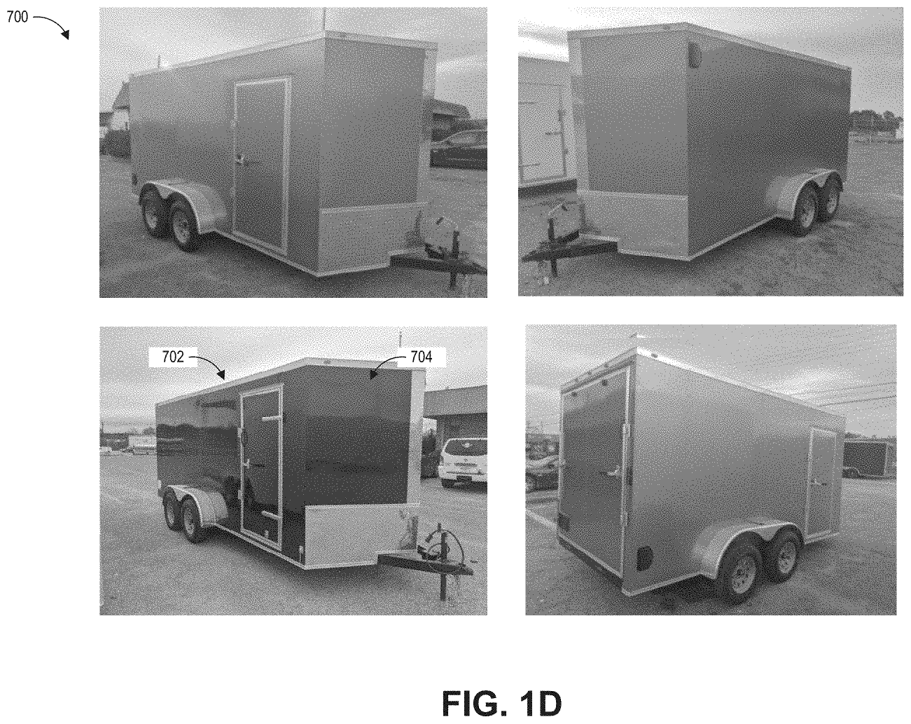

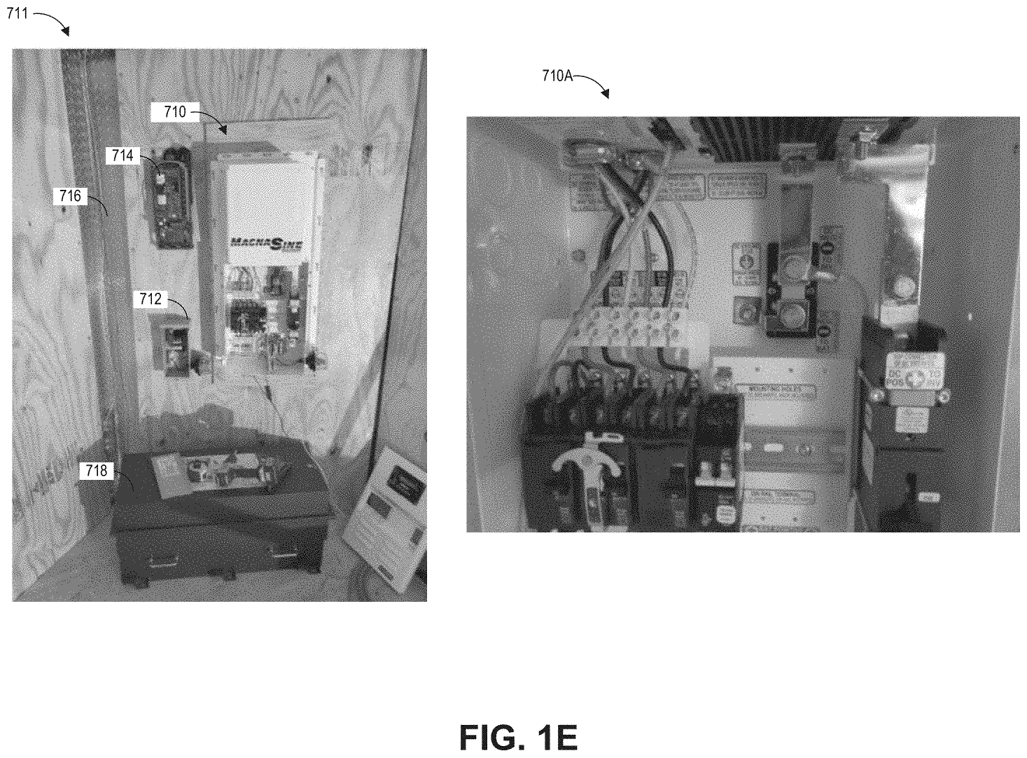

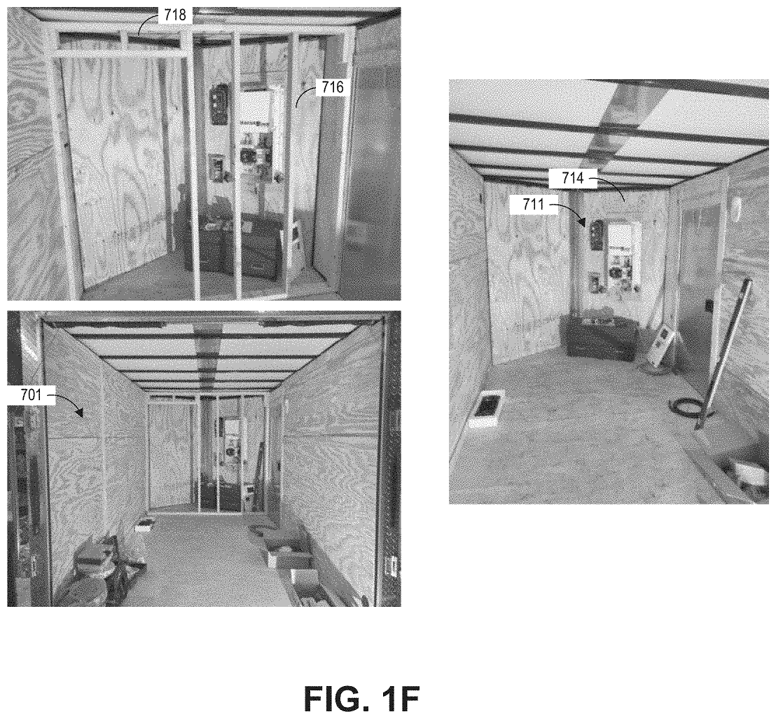

FIG. 1A illustrates a solar power system 100 that can be implemented on a transportation system 110. The transportation system 110 can include any suitable transportation vehicle or container, such as a truck, a truck trailer, semi-trailer, cargo trailer, work boat, cargo boat, freight train, a cargo container, or other vehicle or container. For example, the transportation system 110 can include a truck 120 and a refrigerated trailer 121 for use in shipping perishable freight. Other applications for the solar power system 100 may also be possible. For example, the solar power system 100 can be coupled to a non-commercial mobile vehicle, such as a pleasure boat, recreational vehicle (RV), golf cart, or mobile home. In another example, the solar power system 100 can be applied to non-mobile or semi-mobile structures to enable off-grid or semi-off grid power supply. In another example, one or more aspects of the solar power system 100 may be applied to portable structures or objects, such as backpacks, tents, stands, or other portable and/or temporary devices or structures. In another example, the solar power system 100 can be connected to provide power to a vehicle lift gate, HVAC unit, trickle charge batteries, lighting after or during catastrophic events (tornados, hurricanes, earthquakes, storm aftermath, floods, water purification, community food preservation, electrical blackouts, etc.

The solar power system 100 can include one or more solar packages 111. As described in more detail below, the one or more solar packages 111 can include any number of components. For example, the one or more solar packages 111 can include a support system or layer designed to help prevent damage to solar cells due to road vibrations or other vertical shocks that can occur during transport. In some examples, the one or more solar packages 111 can include a reinforcement material 220 that may provide rigidity or reinforcing structure, be conductive and/or improve the efficiency of the solar power system 100. The one or more solar packages 111 can include a protective or encapsulating layer that can help prevent damage to solar cells due to damage that can occur during transport of the trailer or container upon which the solar power system is disposed.

The solar power system 100 can be disposed on the transportation system 110 at the time of manufacture or through a retrofitting. For example, the solar power system 100 can be disposed on the transportation system 110 by applying one or more solar packages 111 to a sun-exposed surface 130 using an adhesive, as described below. The one or more solar panel packages 111 may be covered in an encapsulating layer 210, as described below.

During a manufacture or retrofitting process, the solar power system 100 can be electrically connected to one or more components of the transportation system 110. For example, components of the transportation system 110 can require a power source (for example, a refrigeration system 126). The solar packages 111 of the solar power system 100 can be electrically connected to components of the transportations system 110 that require power. In another example, the solar packages 111 can be electrically connected to a battery system 124 for storing power. Other electrical connections to and from components of the solar power system 100 can also be made at vehicle manufacture or during retrofitting. For example, electrical connections to one or more power components 122 can be made during a retrofitting process. Some electrical connections can be made before the retrofitting process and some electrical connections can be made during the retrofitting process. For example, the solar packages 111 can be connected to one or more power components 122 at manufacture of the solar packages 111 and the solar packages 111 can be connected to a battery system 124 during a retrofitting process. In another example, the solar packages 111 can be connected to the one or more power components 122 and the battery 124 during one or more steps of a retrofitting process.

A transportation system 110 may include one or more components such as a truck 120 or refrigerated trailer 121, a refrigeration system 126, and at least one sun exposed surface 130. In some examples, a transportation system 110 and/or solar panel system 100 can include some combination of power components (for example, one or more power controller components 122, a display system 123, and/or a battery system 124),

The one or more power components disposed on a transportation system 110 can include some combination of energy storage, power converters, power regulators, power generation components or other suitable components for generating, regulating, or manipulating power. For example, the power components can include one or more solar charge controllers, such as a Schneider Conext™ 60 Amp MPPT Charge Controller 21-60 VDC. The charge controller can include one or more temperature sensors and may have a maximum input of 150 VOC. The power components can include one or more surge protectors, such as a MidNite Solar MNSPD-115 115 VDC 90 VAC Lightning Arrestor or MidNite Solar MNSPD-300-DC surge protector for DC nominal and 250 volts AC nominal. The power components can include one or more circuit breakers, such as a Schneider Electric 865-1070 XW Circuit Breaker. The power components can include one or more inverters, such as a Schneider Conext™ XW6848-120/240-60 Sine Wave Inverter/Charger 48V 6.8 kW Battery System, Magnum Energy™ Sine Inverter Charger, Xantrex™ Inverter/Charger, or the like. The power components can include one or more power distribution components, such as a Schneider Electric Conext™ XW+865-1015-01 Power Distribution Panel. The power components can include one or more system control panels, such as a Schneider Electric Conext™ 865-1050-01 System Control Panel (SCP) for XW+ and SW series inverters. The power components can include one or more communication or monitoring components, such as a Schneider Electric Conext™ ComBo 865-1058. The power components can include one or more generator starts, such as a Schneider Electric Conext™ XW+& SW Automatic Generator Start 865-1060-01. The power components can include one or more battery monitors, such as a Schneider Electric Conext™ Battery Monitor 24/48 Volts 865-1080-01. The power components can include one or more batteries, such as a Discover 12-48-6650 6.65 KwH AES Lithium-Ion Battery. The power components can be connected to the refrigeration system 126. The power components can be connected to the solar power system 100. For example, one or more of the power components can be connected to the solar power system 100 or the refrigeration system 126 during an installation process of the solar power system 100.

The power components disposed on transportation system 110 can include one or more power controller components 122. The one or more power controller components 122 can include a power converter or a blocking diode. The power converter can convert energy from the power generation component to a form of energy that can be used by the refrigeration system 126. For example, the power generation component can be a solar power system 100. The solar power system 100 can produce varied amounts of power based on available solar radiation. The one or more power controller components 122 can help ensure that excess power is not supplied to a refrigeration system 126 or stored in a battery system 124. In another example, the power generation component can be a solar power system 100 that generates direct current (DC) converted or transformed to (AC) with converter or invertor options for power. A refrigeration system 126 can be connected to the one or more power components 122. The refrigeration system 126 can operate on alternating current (AC) or direct current (DC) power. The one or more power components 122 can, for example, convert DC power from the solar power system 100 to AC power for use in the refrigeration system 126. Additionally or alternatively, the same power controller components 122 or different power components can convert power from a battery system 124 for use in a refrigeration system 126.

The one or more power controller components 122 disposed on the transportation system 110 can be connected to a battery system 124. The battery system 124 can include a battery or battery bank that can store power originating from the power generation components. The battery or batteries within a battery bank can be made of a suitable chemical component, such as lithium ion or lead acid. The battery or total battery bank can have a useful capacity of 5-100 kWh. For example, a battery can have a 10 kWh useful capacity. The battery system can have enough useful storage capacity to serve as a backup power source when the power generation component is not generating sufficient power. For example, a power generation component can be a solar power system 100 that cannot generate sufficient power when the sun is occluded or at night. The battery system 124 can have enough useful storage capacity to provide the refrigeration system 126 with sufficient power to cover a typical night period. For example, the battery system can have enough useful capacity to power the refrigeration system 126 for 12 to 24 hours when the refrigeration system 126 is operating to maintain a temperature of between −5° C. and 20° C.

In some examples, a display 123 may be disposed onto a portion of the solar power system 100 or transportation system 110. The display 123 may be configured to display information relating to the solar power system 100, such as the amount of power in or out of the battery system 124. Additionally or alternatively, the display 123 may be configured to display the amount of power remaining in the battery system 124. In some examples, the one or more power components can be configured to wirelessly or with wires communicate with a user device, mobile device, computer, database, the like or a combination thereof. In some examples, battery and/or system information may be stored in local or remote storage for current or future access by a user. Advantageously, remote storage of system information may allow a user to access status information of a solar power system 100 from a remote location, such as while a vehicle is parked and a driver or user is away from the vehicle.

In some examples, one or more power components can include an external power access (such as external power access 712 illustrated in FIG. 1E). An external power access can interact with other power components so as to facilitate removal and/or addition of power to the battery system 124. Additionally or alternatively, the external power access may facilitate direct use of actively generated power from one or more solar panel packages 111. Advantageously, the external power access may help ensure full power in the battery system even when conditions for solar power generation are not favorable. For example, the external power access may allow a user to plug the battery system in for charging to an external power source.

In some examples, one or more of the power components, such as the power controller components 122, battery 124, or other components can be attached, disposed, or secured onto one or more parts of the transportation system 110. For example, the one or more power components may be secured within one or more weather resistant boxes that may in turn be secured onto the exterior of the transportation system 110, such as the front, side, underside, or other portion of the transportation system 110, such as the trailer. In some examples, the one or more power components may be secured on the interior of the transportation system 110. In some examples, some of the one or more power components may be secured on the interior and some of the one or more power components may be secured on the exterior of the transportation system 110. For example, a battery system 124 may be secured in a weather resistant box on the exterior of the trailer and power controller components 122 may be secured on the interior of the trailer. In some examples, the one or more power components may be secured onto different portions of an exterior of the trailer. For example, as illustrated in FIG. 1A, a battery system 124 may be secured onto an underside of a trailer and other power components, such as power controller components 122, may be secured onto a side of the trailer. However, other configurations are also possible.

The refrigeration system 126 can include some combination of refrigeration components such as a fan, evaporator, engine, compressor, and condenser. The refrigeration system 126 can help consistently maintain an approximate temperature within an interior of the trailer 121. The refrigeration system 126 can be able to maintain temperatures within the range of −5° C. and 20° C. For example, the refrigeration system 126 can maintain a temperature of −5° C. The refrigeration system 126 can draw power from a power source in order to maintain a desired temperature within the interior of the trailer 121. The refrigeration system 126 can require a supply voltage of between 200 and 500 volts. For example, the refrigeration system 126 can require a supply voltage of 440/460 volts. In another example, the refrigeration system 126 can require a supply voltage of 208/230 volts. The refrigeration system 126 can require a current of 30 or 100 amps. For example, the refrigeration system 126 can require a minimum current of 50 amps. The refrigeration system 126 can be able to run on a utility frequency of between 50 and 60 Hz. For example, the refrigeration system 126 can run on a utility frequency of 50 Hz. Additionally or alternatively, the refrigeration system 126 can be able to run on a direct current (DC) supply. The source of AC or DC power can be any suitable power source. For example, the solar power system 100, a stationary solar array, or electrical grid system can provide an AC or DC supply and the refrigeration system 126 can be able to run on the power supply provided from those or other suitable sources of DC power.

The sun exposed surface 130 can be a surface of the truck or trailer capable of being exposed to sunlight. For example, the sun exposed surface 130 can be a surface of the truck 120 or trailer 121 that is not covered by shadow or another component of the truck or trailer 121. The sun exposed surface 130 can include a roof or side walls of the truck 120 or trailer 121. The sun exposed surface 130 can optionally include an insulated material. The sun exposed surface 130 can include a metallic outer surface.

### II. Example System Configuration

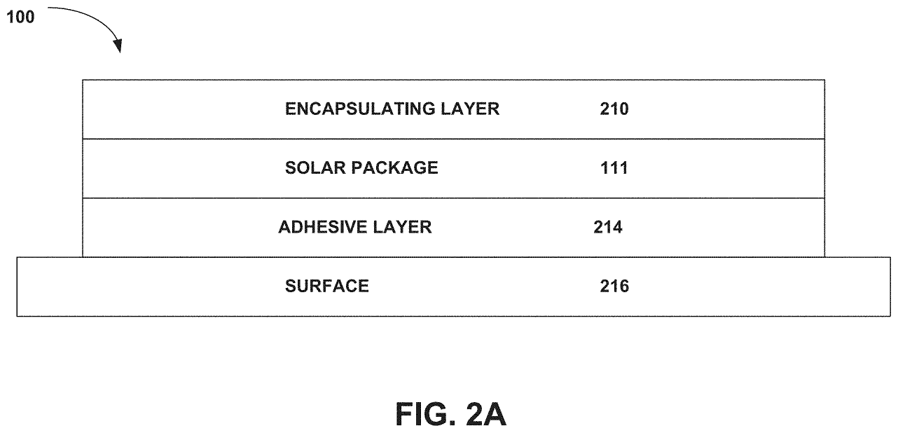

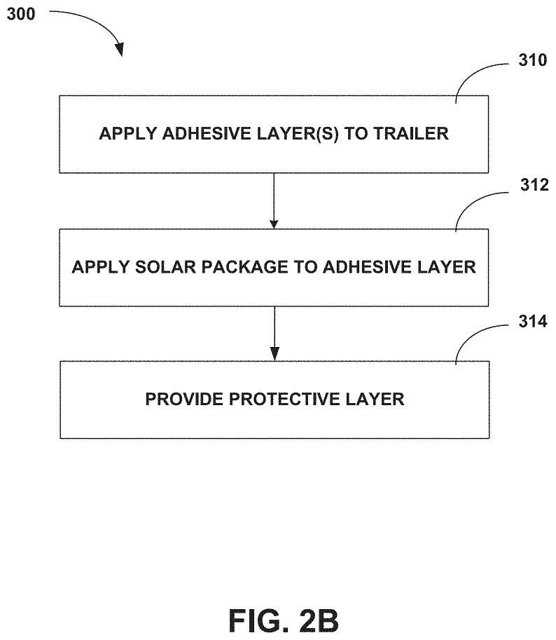

FIGS. 1B-1, 1B-2, 1C-1, and 1C-2 illustrate top and side views of embodiments of a solar power system 100 that can be disposed on a sun-exposed surface 130 of a transportation system 110. The solar power system 100 can include one or more solar packages 111. For example, the solar power system 100 can include two sets of solar packages 111. In the example illustrated in FIG. 1B-1, the solar power system 100 includes two sets of twelve solar packages 111. In the example illustrated in FIG. 1B-2, the solar power system 100 includes six solar packages 111. However, any number of configurations are also possible, such as a single solar panel package 111, or one, two, three, or more sets of one or more solar packages 111, or some other suitable configuration.

The solar power system 100 that can cover any percentage of a sun-exposed surface 130. For example, the solar power system 100 can cover 20%, 45%, or 90% of the roof of a truck trailer. The coverage area of the surface can be related to a desired power output of the solar power system 100. For example, a refrigeration system coupled to a truck trailer can require 4 kW over the course of an hour and the solar power system 100 can generate 5 kW per hour when covering 100% of the roof of the truck trailer. Thus, the solar power system 100 that can cover 80% of the roof of the truck trailer in order to generate only the amount of needed power and reduce weight.

Additionally or alternatively, the solar power system 100 can be provided to other surfaces. For example, the solar power system 100 can be provided to an extension of the sun-exposed surface 130 or the solar power system 100 itself can extend beyond the sun-exposed surface 130. The solar power system 100 can be provided to other parts of truck 120 or trailer 121. For example, the solar power system 100 can be provided to the cab area 132 of the truck 120.

There can be more than one solar power system 100 in the truck trailer power system 100. For example, there can be a solar power system 100 provided to a sun-exposed surface 130 that can provide power to a trailer 121 and there can be a solar power system 100 provided to a surface of a cab area 132 of the truck 120 to provide power to the cab area 132. Additionally or alternatively, a solar power system 100 can be provided to other areas of the truck 120.

The solar power system 100 can be substantially flat or substantially parallel to a sun-exposed surface 130 or other surface upon which the solar power system 100 is disposed. The solar panel packages 111 in the solar power system 100 can be between ¼″ and 6″ thick. For example, the solar power system 100 can be ⅛″, ¼″, ½″ or ¾″ thick. Advantageously, ¼″ thickness provides a more aerodynamic posture. A thicker solar power system 100 can include further layers of support and protection from damage that cannot be possible with a thinner solar power system 100. For example, as will be discussed below, a solar panel package 111 within a solar power system 100 can include a support layer with shock absorbing foam. The foam can add additional height to the configuration. For example, the foam can be 1″ thick. Thus, the solar power system 100 may, for example, be 1¼″ thick when 1″ is added to the solar panel package 111. A maximum height of the solar power system 100 can be dictated by height of the transportation system 110. For example, a transportation system 110 can be some combination of a truck 120 and trailer 121. The total truck 120 and trailer 121 height can be capped by regulations at a maximum height of 13′6″ or 15′. The solar packages 111 in the solar power system 100 can be any suitable dimension. A minimum dimension of the solar packages 111 can be dictated by power needs. For example, in general, the larger a solar cell (which can be contained within a solar panel package 111), the more photon conversion area. Advantageously, with increased photon conversion area, power generation will generally also increase. A maximum size of the solar packages 111 can be dictated by the size of the surface upon which they are disposed. For example, a sun-exposed surface 130 can be 102″ wide, so the solar packages 111 can be up to 102″ wide. In another example, a sun-exposed surface 130 can be 40′ long, so the solar packages 111 can be up to 40′ long. In another example, a sun-exposed surface 130 can be 53′ long, so the solar packages 111 can be up to 53′ long. The dimensions of a solar panel package 111 can be less than the maximum size of the surface upon which it is disposed. For example, a solar panel package 111 can be 50″ long. Advantageously, making the dimensions of a solar panel package 111 smaller than the full dimensions of a sun-exposed surface 130 can ease repair costs and other considerations. For example, if a solar power system 100 includes a single solar panel package 111 that is the full dimensions of a sun-exposed surface 130, then even a small area of damage would require repair of the entire solar panel package 111. If a solar power system 100 includes twenty four solar panel packages 111, then a small area of damage can be limited to a limited number of solar panel packages 111 and only that limited number would require repair. Thus, costs can be lowered for repair with dimensions less than the full size of the sun-exposed surface 130.

In some examples, one or more portions of the solar power system 100 can have a weight per square foot less than 1 pounds, 0.6 pounds, 0.5 pounds, or any other weight per square foot. The weight per square foot may be approximately the same for one or more different sizes of the solar power system 100. For example, an embodiment of a solar panel package of a solar power system 100 of a size of about 14 inches by 23 inches (or about 36 cm by about 58 cm) may have a total weight of about 1.2 pounds (or about 0.54 kg) and/or a weight (in lbs) per square foot of about 0.537. In another example, an embodiment of a solar panel package of a solar power system 100 of a size of about 14 inches by 23 inches (or about 36 cm by about 58 cm) may have a total weight of about 1.25 pounds (or about 0.57 kg) and/or a weight (in lbs) per square foot of about 0.559. In another example, an embodiment of a solar panel package of a solar power system 100 of a size of about 20 inches by 29 inches (or about 51 cm by about 77 cm) may have a total weight of about 2.2 pounds (or about 1 kg) and/or a weight (in lbs) per square foot of about 0.546. In another example, an embodiment of a solar power system 100 of a size of about 20 inches by 29 inches (or about 51 cm by about 77 cm) may have a total weight of about 2.25 pounds (or about 1.02 kg) and/or a weight (in lbs) per square foot of about 0.559.

In some examples, one or more solar panel packages 111 may be configured to be disposed onto the surface of the trailer 130, such as illustrated in FIG. 1C-1. In some examples, one or more solar panel packages 111 may be configured to be disposed onto one or more movable components 150, such as illustrated in FIG. 1C-2. It is of note that while FIG. 1C-2 illustrates a single movable component, a system may include a plurality of movable components 150. A movable component 150 can include a hinged or otherwise movable, foldable, or collapsible panel configured to lie against a portion of the transportation system 110, such as the trailer 130, when not in use. The movable component 150 may be supported by one or more support structures, such as one or more pistons 152 or other structural components capable of maintaining the weight and location of the movable component 150 during use, such as one or more support bars 154. In some examples, the movable component 150 may be raised in order to place one or more solar panel packages 111 that may be disposed on or a part of the movable component 150, such as the one or more support bars 154, so as to capture sunlight in one or more solar cells in the solar panel package 111. For example, the one or more movable components 150 may be configured to raise one or more solar panel packages 111 that may disposed on or as a part of the movable component 150 to be approximately flush and/or approximately parallel to one or more solar panel packages 111 disposed onto a surface of the trailer 130. It is of note that while the example shown in FIG. 1C-2 illustrates a placement of the movable component 150 as parallel to the ground and/or the top of the trailer 130, an angle θ of the movable component 150 and/or solar panel packages 111 disposed on or part of the movable component 150 may be at any suitable angle, such as less than or greater than 90 degrees from a side of the transportation system 110. In some examples, the angle θ of the movable component 150 may be 20 degrees, 35 degrees, 50 degrees, 110 degrees, 160 degrees or another angle in relation to the side of the trailer. In some examples, the angle of the movable component 150 may be determined based on desired clearance at the sides of the trailer. For example, the movable component 150 may be angled to raise at least a portion of the movable component 150 and/or solar panel package disposed on or a part of the movable component 150 above a height of the trailer or vehicle so that the trailer or vehicle may be parked in a location with less clearance around the sides of the trailer.

In some examples, one or more movable components 150 can be disposed onto one or more sides of the transportation system 110. The one or more movable components 150 may be disposed during vehicle or trailer manufacture or as part of retrofitting a vehicle or trailer. For example, a transportation system 110 may have a side portion corresponding to a driver side 112A, a side portion corresponding to a passenger side 112B, a front portion corresponding to a front of the trailer 113A and a back portion corresponding to a back of the trailer 113B. A movable component 150 may be disposed onto one or more of the two side portions, front portion, or back portion. Advantageously, the movable component 150 may facilitate use of a greater number of solar cells and/or allow for a greater amount of power generation based on user need. In some examples, a movable component 150 may be disposed onto a top portion of the trailer 130 in order to facilitate movement of one or more solar panel packages 111 for better placement of the one or more solar panel packages 111 for capture of sunlight and production of power. For example, the one or more movable components 150 may allow for the one or more solar panel packages 111 to face south in appropriate areas to capture the more direct south facing sun. In other examples, the one or movable components 150 may move dynamically or be customizable so as to facilitate capture of sunlight based on time of day, parking direction of the transportation system 110, or other parameter related to the capture of sunlight by the solar power system 100. In some instances, the angle of the movable component with respect to a surface of the trailer, such as a surface of a side portion corresponding to a driver side 112A or passenger side 112B of a trailer, may be automatically determined based on location data received from GPS (global positioning service) device on a transportation system (or a mobile device) and time of day.

The one or more movable components 150 and/or solar panel packages 111 can be of any size or shape according to user need or desire. For example, a movable component 150 disposed onto the side of a trailer 130 may be approximately the size and shape of the side of the trailer 130. In other examples, the movable component 150 may be smaller than the size and shape of the side of the trailer 130. In other examples, the movable component 150 may be a different size and/or shape than the side of the trailer. In some examples, the movable component 150 may be foldable. In some examples, the movable component may be a static or dynamic size and/or shape.

In some examples, the one or more movable components 150 can include one or more electrical connections or components. For example, the one or more movable components 150 may include one or more controllers, actuators, solar panel packages 111, or other components configured to control the movement or function of portions of the movable component 150, such as a solar panel package 111. The one or more electrical connections or components may be electrically connected to other electrical components in the solar power system 100, such as the one or more power controller components 122 or battery system 124. In some examples, one or more support or control systems for moving the movable component 150 may be electrically connected to the battery 124 such that the battery may provide power to the one or more support or control systems. In other examples, the one or more electrical components of the movable component(s) 150 can include one or more transmitters and/or receivers capable of transmitting or receiving signals related to controlling the movement and/or operation of the one or more movable components 150.

In some examples, the solar power system 100 may include one or more securing components 156 configured to secure the one or more movable component(s) and/or solar panel package(s) to a side of the trailer or other object or surface upon which the movable component(s) is attached. For example, a securing component 156 can include a clasp, fastener, clip, pin, hook, buckle, lock, the like or combination thereof. Advantageously, a securing component may allow the system to securely transport the trailer or other object and help prevent damage to the solar panel system as a result of transport and/or impact damage due to transport.

In some examples, the solar power system 100 may include one or more support components 154 configured to secure at least a portion of the movable component(s) 150 and/or solar panel package(s) 111 to the vehicle or trailer. For example, the support portion 154 may include one or more hinges. The one or more hinges can be configured to secure a top edge of the movable component(s) 150 and/or solar panel package(s) 111 to a top edge or other portion of the vehicle or trailer.

### III. Example Implementation of a Solar Panel System

FIGS. 1D-1F illustrate views of an example implementation of an embodiment of the solar panel systems and methods described herein. FIG. 1D illustrates external views of an example carry on trailer implementation of an embodiment of a solar power system. FIG. 1E illustrates views of an example electrical setup that may be associated with an example implementation. FIG. 1F illustrates internal views of an example carry on trailer implementation of an embodiment of a solar power system.

As illustrated in FIG. 1D, a solar panel system may be disposed onto a carry on trailer. In some examples, a solar panel system 100 can be disposed onto a top portion 702 of the carry on trailer 700 such that the solar panel system 100 is sun exposed. However, the solar panel system 100 can be disposed on any suitable surface of the trailer 700. While a carry on trailer is illustrated, it will be appreciated that the solar panel system 100 may be disposed on other types of vehicles, trailers, or the like.

In some examples, a carry on trailer can be outfitted with one or more electronic components that are configured to interact with the solar panel system 100. The one or more electrical components may be disposed onto a portion of the trailer, such as on an interior or exterior of a front portion 704. In some examples, electronic components can include one or more power components such as described above. FIG. 1E illustrates views of example electronic components 711 that may be disposed on or within a trailer 700. For example, as illustrated in FIG. 1E, power components can include a power inverter 710, charge controller 714, external power supply or plug 712, power connection 716, and/or battery 718. Inset 710A illustrates an example configuration of an example power inverter that may be configured to interact with the solar panel system 100. It is of note that the electronic components 711 may be similarly or otherwise suitably configured in another transportation system 110 or other application of a solar power system 100.

In some examples, a power connection 716 can include a connection of the one or more electronic components 711 to one or more solar panel packages 111. In the illustrated example in FIG. 1E, a power connection 716 is align along the front peak of the interior portion of the trailer 700. The power connection 716 may include one or more cables configured to lie along a wall, corner, or other portion of the trailer 700 and connected to one or more solar panel packages 111 on the exterior of the trailer 700. In some examples, the power connection 716 may be fed through a feed through connector from the interior to the exterior of the trailer 700. It is of note that a power connection 716 to/from a solar panel package 111 to/from one or more electronic components in another transportation system 110 or other application of a solar power system 100 may be similarly or otherwise suitably configured.

FIG. 1F illustrates views of an interior 701 of the trailer 700. In the illustrated example, one or more electronic components 711 can be disposed onto a portion of the interior of the trailer 700. For example, one or more electronic components 710 may be mounted, attached, or otherwise disposed onto an interior wall 714 of the trailer 700. The one or more electronic components may be electrically connected to a solar power system disposed on another portion of the trailer 700, such as the top portion 702 of the trailer 700. In some examples, the one or more electronic components may be concealed within the trailer behind, for example, a wall or other covering. Advantageously the wall or other covering may help prevent cargo from interacting with the one or more electronic components 711. FIG. 1F illustrates an example stud wall 716 that may be part of an example electronic components covering. In some examples, the electronic components covering may include one or more access portions configured to allow a user to access the one or more electronic components. In the example illustrated in FIG. 1F, the stud wall 716 can include an example doorway 718 to facilitate user access to the one or more electronic components 710.

In some examples, one or more of the electronic components may be disposed on the exterior of the trailer 700. One or more coverings, such as a weather resistant box may be disposed over the one or more electronic components in order to protect the one or more electronic components from road and/or weather wear.

### IV. Solar Power System

FIG. 2A illustrates a block diagram of an example solar power system 100. For example, the solar power system 100 can include a number of layers disposed onto a surface 216. As illustrated, the solar power system 100 can include some combination of an adhesive layer 214, a solar panel package 111, and an encapsulating layer 210.

The surface 216 on which the solar panel package 111 can be disposed can be composed of any suitable material. For example, the surface 216 can be a container or sun-exposed surface 130 (as shown in FIGS. 1A-1C). The surface 216 can be composed of a metal, such as aluminum. The surface 216 can include other types of surfaces or substrates that can cover a roof surface of a transportation system 110. For example, surface 216 can be a protective coating for the surface 216, such as a plastic resin. In another example, the surface 216 can be a flexible material, such as fabric.

The encapsulating layer 210 can be a layer or multiple layers that can help prevent damage to solar cells in the solar panel package 111 that can occur due to impacts from debris or other source of damage during transport of goods being cooled by the solar power system. The encapsulating layer 210 can allow light to transmit through the encapsulating layer 210 to the solar panel package 111. For example, the encapsulating layer 210 can be composed of a transparent plastic material. The encapsulating layer 210 can be composed of at least one protective film. For example, the encapsulating layer 210 can be composed of a laminate film or multiple laminate films. The encapsulating layer 210 can be applied through a heat application process. For example, the encapsulating layer 210 can be composed of a laminate film and the layer can be applied by melting or partially melting the film onto the solar panel package 111.

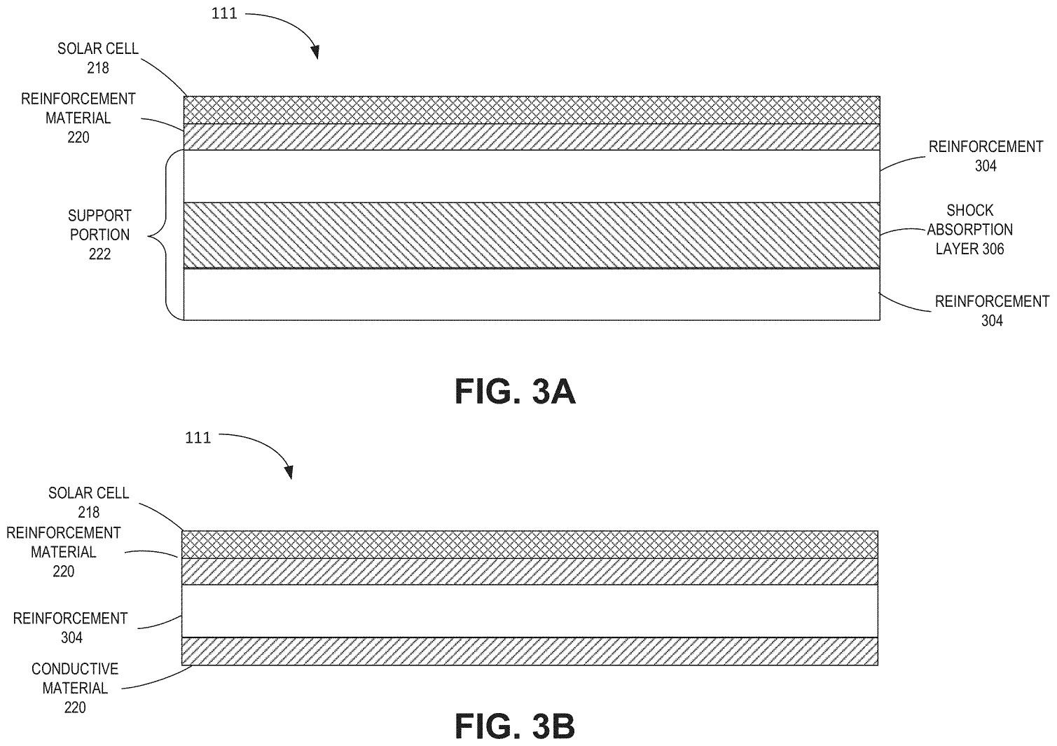

Additionally or alternatively, the encapsulating layer 210 can include an ink layer. The ink layer can be disposed onto another portion of the encapsulating layer 210 or onto the solar panel package 111. For example, the encapsulating layer 210 can include a laminate film. The ink layer can be disposed on top of the solar cells to obscure the string lines on the solar panel. In another example, the ink layer can be disposed directly on top of the solar panel package 111. The ink layer can be disposed onto the entirety or a portion of the solar power system 100. For example, the solar power system 100 can include a solar panel package 111. The solar panel package 111 can include a solar cell layer 218 (as shown in FIGS. 3A and 3B). The solar cell layer 218 can include electrical leads or connections. The electrical leads or connections can form a pattern on top of the solar cell layer 218. The ink layer can be one or more layers of ink disposed onto the electrical leads such that the electrical leads are less immediately visible to the unaided human eye. Thus, the ink layer may increase the aesthetics of the solar power system 100.

The solar panel package 111 can be a system consisting of a layer of materials designed to capture photon energy for conversion into electricity. As will be discussed below, the solar panel package 111 can include some combination of support materials, conductive materials, and solar cells.

The adhesive layer 214 can be one or more layers of material configured to adhere the solar panel package 111 to the surface 216. For example, the surface 216 can be an aluminum surface of a trailer and the adhesive layer can include an adhesive bond or adhere to the aluminum surface. The adhesive layer 214 can include a resin, such as an epoxy or polyester resin. The adhesive layer 214 can further include another material that can reinforce or provide support to the solar power system 100. The adhesive layer can include more than one layer of adhesive material. For example, the adhesive layer 214 can include two or more layers of adhesive. There can be more than one adhesive layer 214 in the system 100. The adhesive layer can be between any two or more layers of the system 100.

The solar power system 100 that can adhere to a surface with or without the need for further structural support, such as a frame or other support attached using mechanical means to the truck sun-exposed surface 130. The solar power system 100 can be permanently applied to a surface 216. For example, as will be described below, the solar power system 100 can include an adhesive layer 214 that can bond with the sun-exposed surface 130. Additionally or alternatively, the solar power system 100 can be attached to the surface 216 by adhesive materials such as tape, epoxy resins, or other combinations of chemicals to create a bond between the surface 216 and the solar power system 100. Additionally or alternatively, the solar power system 100 can be removably applied to a surface 216. For example, the solar power system 100 can be applied to an intermediary material or surface other than the surface 216. The intermediary surface can couple to the surface 216 through mechanical or other means, such as with an adhesive or through adhesive bonding.

FIG. 2B illustrates an example solar power system application process 300. The solar power system 100 can be applied with a frame or without a frame or similar structure. The process 300 can involve applying an adhesive layer 214 to a surface 216 in one or multiple steps 310. The process can involve disposing the solar panel package 111 to the adhesive layer 214 in a step 312. The process can further involve applying an encapsulating layer 210 in a step 314.

At a step 310, the adhesive layer 214 can be applied to a surface 216. The adhesive layer 214 can secure the one or more solar panel packages 111. For example, the adhesive layer 214 can be a bonding adhesive that can bond to an aluminum surface of the surface 216, such as 3M™ Panel Bonding Adhesive or Valvoline™ Pliogrip two part adhesive. In another example, the adhesive layer 214 can include adhesive sealing tape, such as 3M™ Extreme Sealing Tape. The adhesive layer 214 can be applied across the entirety of the area of the surface 216 to which the solar power system 100 can be disposed or a portion of the area of the surface 216 to which the solar power system 100 can be applied. For example, the adhesive layer 214 can be applied on the edges of the solar power system 100 and/or the adhesive layer 214 can be applied in a pattern on the surface 216.

At a step 312, at least one solar panel package 111 can be disposed onto the adhesive layer 214. The solar package(s) 111 can be disposed in any suitable configuration. For example, as illustrated in FIGS. 1A-1C, one or more solar packages 111 can be disposed on a driver side 112A of a truck trailer or container and one or more solar packages 111 can be disposed on a passenger side 112B of a truck trailer or container.

At a step 314, a encapsulating layer 210 can be applied to the solar packages 111. The encapsulating layer 210 can be a transparent material that can allow light to pass into the solar package. The encapsulating layer 210 can protect the solar power system 100 in whole or in part from excess contact or collision damage that can occur during transport of the trailer or container, from excess moisture, or other potential sources of damage to the solar power system 100. The encapsulating layer 210 can be applied by molding, melting, or partially melting a material over the one or more solar packages 111. The encapsulating layer 210 can be applied over the entirety of the solar power system 100 or part of the solar power system 100. The encapsulating layer 210 can be applied to an area larger than the one or more solar panel packages 111 in the solar power system 100. For example, the one or more solar panel packages 111 in the solar power system 100 can partly cover the roof area of a truck trailer or container. The encapsulating layer 210 can cover the one or more solar panel packages 111 and cover the roof area of the truck trailer or container that the one or more solar panel packages 111 do not cover.

While specific layers are described herein, other layers can be applied in order to provide the solar power system with further structure and support during transport of a trailer or container upon which the layers are coupled or disposed. While individual layers can be described, each individual layer can appear multiple times in a suitable order as part of a solar panel package 111 disposed on surface 216. Each layer can include a single layer or include multiple layers within it. While an order of layers can be described, other orders of layers can be applied.

### V. Solar Panel Package

FIGS. 3A-3B show block diagrams of example solar packages 111 that can be part of a solar power system 100. For example, a solar panel package 111 can include some combination of a support portion 222 (which can include reinforcement 304 and/or a shock absorption layer 306), a reinforcement material 220, and a solar cell layer 218. Each portion can appear a single time or multiple times in a suitable order. Each layer or portion can include a single layer of material or include multiple layers of material. Some configurations can include fewer combinations of portions or layers and some configurations can include more combinations of layers. For example, the solar power system 100 can include internal layers of composite materials such as: fiberglass, extruded chemical foams, honeycomb material, balsa wood, core cell or other forms of structural foam, carbon fiber, carbon nanotubes or other forms of carbon structures.

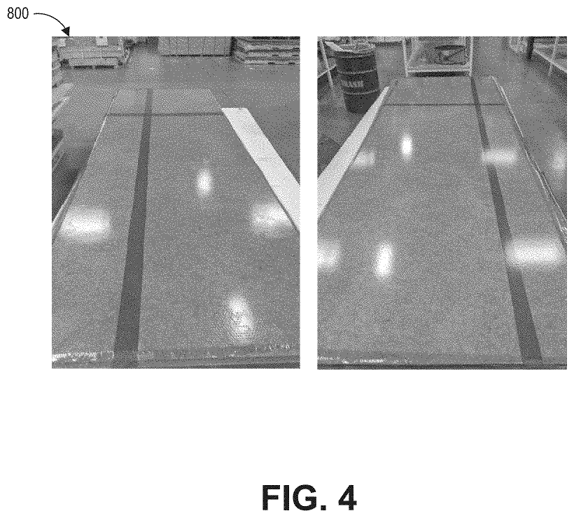

Portions of the solar panel package can be configured to be any share or size. For example, the support portion 222 can be configured to be of a similar size to a portion of the surface on which the solar panel package may be disposed. In other examples, the support portion 222 can be smaller or of a different shape than the available surface on which the solar panel package may be disposed. FIG. 4 illustrates an example support portion 800 that may also include a reinforcement material 220 having a similar size to a top portion of a carry on trailer (such as the trailer 700 illustrated in FIGS. 1D-1F). In some examples, one or more other components of the solar panel package may be disposed onto the support portion 800.

The reinforcement 304 can include a sheet of supportive material. For example, the reinforcement 304 can be a flat sheet of material that is produced through a continuous molding process, such as pultrusion. The reinforcement 304 can include a reinforcing material, such as a fiberglass roving, mat, or cloth that is impregnated with a resin. The fiberglass material can be an E-glass epoxy composite material or other type of fiberglass material, such as S-Glass epoxy composite. The composite materials can be bonded or encapsulated with resins, pre-impregnated epoxy resins or other chemical materials. The reinforcement 304 can include multiple layers of reinforcement material. For example, the reinforcement 304 can include layers of fiberglass roving and fiberglass cloth to provide extra support.

The shock absorption layer 306 can be one or more layers that can help absorb some vertical or other shocks and/or vibration that can occur during transport of the solar power system 100. For example, the shock absorption layer 306 can include an energy absorbing material, such as a polyethylene, polystyrene, polypropylene, polyurethane, rubber, or other suitable material. For example, the shock absorption layer 218 can be composed of a polyethylene foam material, such as PET foam core. Additionally or alternatively, the energy absorbing material can be a foam structure or other suitable energy absorbing structure, such as a honeycomb structure. In another example, the shock absorption layer 306 can be composed of a material shaped into a geometric configuration within the layer that can allow the layer to deform under force. For example, the geometric configuration can include hexagonal-shaped cells or other suitable structure. The geometric cells can be a single size or multiple sizes and a single configuration or multiple configurations. The shock absorption layer 306 can be composed of more than one shock absorption material of one or more types or orientations. For example, the shock absorption layer 306 can be composed of a PET foam core and a honeycomb structural material. The shock absorption layer 306 can include materials that can help absorb vibrations and/or shocks in both vertical and horizontal directions.

There can be more than one shock absorption layer 306 in the solar panel package 111. For example, the one or more solar panel packages 111 can include a shock absorption layer 306 between the surface 216 and the reinforcement 304. There can be more than one type of shock absorption layer in the solar panel package 111. For example, the solar panel package 111 can include two shock absorption layers. Multiple shock absorption layers can be composed of the same type or different types of shock absorption material. For example, there can be two or more shock absorption layers capable of absorbing some of the vibrations and/or shocks in two different directions relative.

Additionally or alternatively, the shock absorption layer 306 and reinforcement 304 can be part of a support portion 222, as illustrated in FIG. 3A. The support portion 222 can include some combination of shock absorption layers 306 and reinforcement 304. The support portion 222 can have supportive properties. For example, the support portion 222 can be composed of a single material that has shock absorption and/or supportive properties.

In some examples, a solar panel package 111 can include a reinforcement material 220. The reinforcement material 220 can include a layer or multiple layers of material capable of providing reinforcement to the solar panel package 111. Advantageously, the reinforcement material 220 can also provide rigidity to the system. The reinforcement material 220 can be composed of a material capable of maintaining rigidity when impregnated with resin and conducting electricity. For example, the reinforcement material 220 can be a conductive carbon fiber layer. The carbon fiber layer can be a carbon fiber reinforced carbon layer, a coated carbon fiber (such as through chemical vapor deposition or CVD), or other suitable alternative.

In some examples, the reinforcement material 220 can include a material capable of conducting electricity. For example, the reinforcement material 220 can be carbon fiber impregnated with resin. The resin can be an epoxy resin or other suitable resin. The carbon fiber can be a carbon twill or other suitable weave. Additionally or alternatively, the reinforcement material 220 can be composed of a conductive material, such as carbon, silver, or other suitable conductive material. The reinforcement material 220 can be placed below the solar cell 218. Advantageously, the conductive material can increase the efficiency of the solar power system 100 by increasing photon capture of the solar cell layer 218.

The solar cell layer 218 can be a layer or multiple layers that can be composed of a photovoltaic material or materials. For example, the solar cell layer 218 can include a solar cell or set of solar cells, such as DG 884 W Solar Power Panels. The solar cells can be composed of a suitable semiconductor material, such as crystalline silicone. The solar cells can be wafer-based cells, thin film cells, or other solar cell type. For example, a solar cell layer 218 can be composed of thin film solar cell(s) that are lightweight. The solar cell layer 218 can have an efficiency sufficient to supplement a power supply or act as the sole power supply for a refrigerated trailer or container when in context of the solar power system 100. For example, the solar panel package 111 may be able to convert solar energy at an efficiency above 5% of the solar cell “nameplate” efficiency. In another example, the solar cell layer 218 may be able to convert solar energy with an efficiency of approximately 15% of the solar cell “nameplate” efficiency, depending on the conductive materials used.

While specific layers are described herein, other layers can be applied in order to provide the solar cell system with further structure and support during transport of a trailer or container upon which the layers are coupled or disposed. While individual layers can be described, each individual layer can appear multiple times in a suitable order as part of a solar panel package 111 disposed on a surface 216. Each layer can include a single layer or include multiple layers within it. While an order of layers can be described, other orders of layers can be applied. For example, as shown in FIG. 3B, a solar panel package 111 can include more than one layer of reinforcement material 220. In another example, as shown in FIG. 3B, a support portion 222 can be entirely or in part replaced by a reinforcement 304.

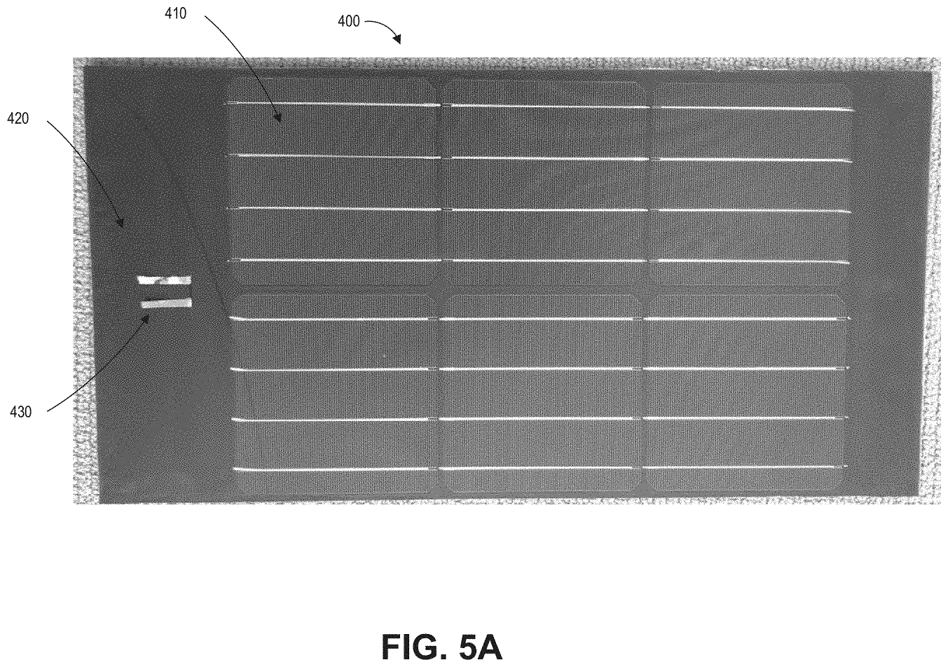

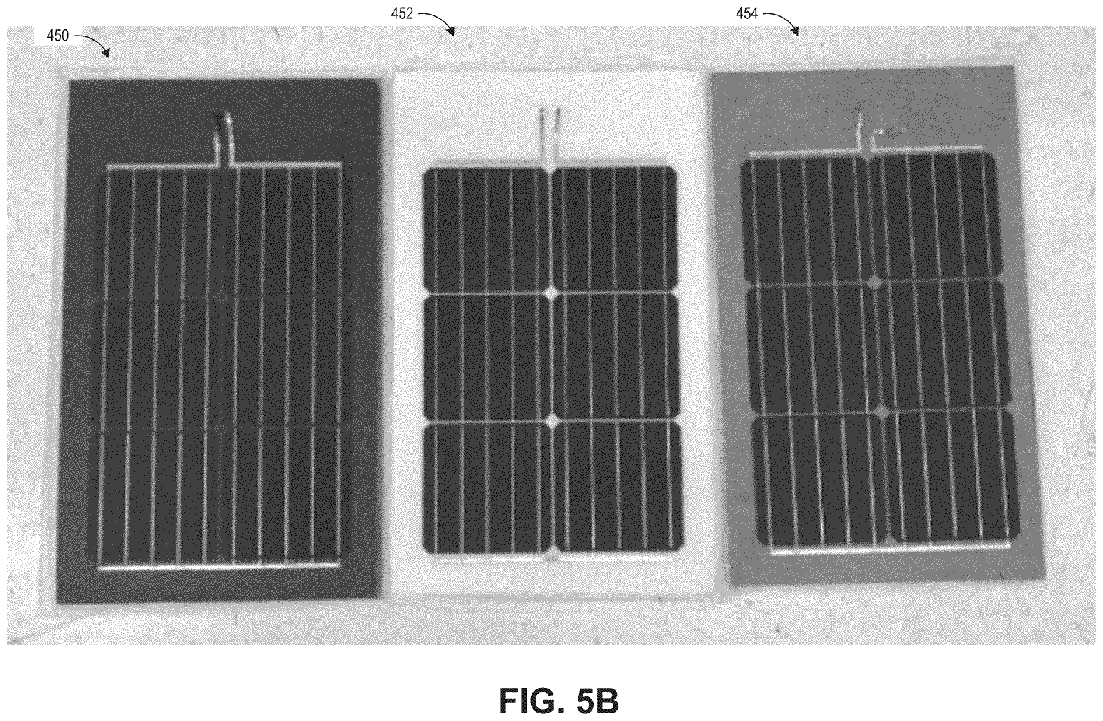

FIG. 5A illustrates an example solar panel package 400. For example, the solar panel package 400 can include a plurality of solar cells 410. The plurality of solar cells 410 may be disposed on top of a structure 420. The structure 420 can include a carbon fiber layer (such as the reinforcement material 220 referenced above) and a support layer (such as the shock absorption layer 306 or reinforcement 304). The solar panel package 400 can include electrical connections or leads 430 for connecting the solar panel package to other electrical systems. The solar panel package 400 can be disposed on a sun exposed surface 130. The solar panel package 400 can be encapsulated by an encapsulating layer 210. The encapsulating layer 210 can include an ink layer that may cover the electrical leads 430 or other electrical components with dark ink so that the solar cells 410 are less apparent to the naked eye.

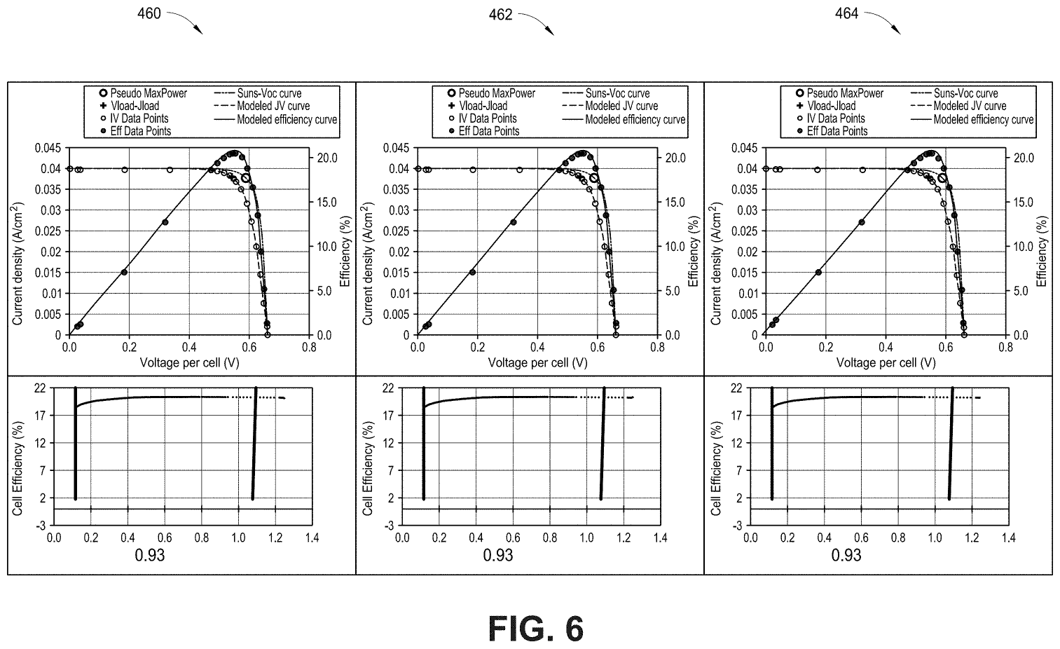

FIG. 5B illustrate example variants of an example solar panel package. For example, a solar panel package can include a black variant 450, a white variant 452, and a grey variant 454. However, other color variants are also possible. The black variant 450 includes a carbon fiber infused variant of the solar panel package that lends the black color to the solar panel package. The white variant 452 is an example of a colored variant of the solar panel package in which an epoxy used in preparation of one of more layers of the solar panel package is pre-impregnated with a white color during manufacturing. It is of note that while a white variant 452 is illustrated, other colors are also possible. A grey color variant 454 is an example of an uncolored variant of the solar panel package. Advantageously, a color variant may allow a solar panel package 111 to be color matched or partially color matched to a surface on which the solar panel package 111 is disposed. For example, a white color variant may be applied to a white trailer. Advantageously, this may provide a more aesthetically pleasing and less visually invasive solar power system. Additionally, a brighter color variant may facilitate an improved efficiency of power generation over a darker solar panel package, such as illustrated in Table 1 below and FIG. 6.

FIG. 6 illustrate example test results 460, 462, and 464 of a black variant 450, white variant 452, and grey variant 454 respectively. Table 1 illustrates example parameters associated with the test results illustrated in FIG. 6. Italicized values in parenthesis correspond to example values associated with solar cells that may be included in respective solar packages.

TABLE 1

| | Black Solar | White Solar | Grey Solar |
|---|---|---|---|
| | Package | Package | Package |
| Parameter | (Black Solar Cell) | (White Solar Cell) | (Grey Solar Cell) |
| PMP | 30.024 W | 30.100 W | 30.368 W |
| | (5.004 W) | (5.017 W) | (5.061 W) |
| Efficiency | 20.57% | 20.62% | 20.80% |
| | (20.57%) | (20.62%) | (20.80%) |
| VOC | 4.03 V | 4.02 V | 4.02 V |
| | (0.6710 V) | (0.6708 V) | (0.6697 V) |
| VMP | 3.26 V | 3.26 V | 3.26 V |
| | (0.544 V) | (0.543 V) | (0.543 V) |
| ISC | 9.762 A | 9.789 A | 9.823 A |
| | (9.762 A) | (9.789 A) | (9.823 A) |
| IMP | 9.204 A | 9.232 A | 9.327 A |
| | (9.204 A) | (9.232 A) | (9.327 A) |
| FF | (76.38%) | (76.40%) | (76.94%) |
| JSC | 0.0401 A/cm² | 0.0402 A/cm² | 0.0404 A/cm² |
| | (0.0401 A/cm²) | (0.0402 A/cm²) | (0.0404 A/cm²) |
| JMP | 0.0378 A/cm² | 0.0379 A/cm² | 0.0383 A/cm² |
| | (0.0378 A/cm²) | (0.0379 A/cm²) | (0.0383 A/cm²) |
| Pseudo FF | (82.7%) | (82.4%) | (82.7%) |
| Pseudo VMP | (0.584 V) | (0.583 V) | (0.582 V) |
| Pseudo JMP | 0.0381 A/cm² | 0.0382 A/cm² | 0.0384 A/cm² |
| RSH (at 0.45 V) | 5112 Ω-cm² | 5825 Ω-cm² | 5599 Ω-cm² |
| RS* (at Jload) | 1.07 Ω-cm² | 1.04 Ω-cm² | 1.03 Ω-cm² |
| T (Vload) | 25.1° C. | 25.3° C. | 25.3° C. |

### VI. Terminology

Many other variations than those described herein will be apparent from this disclosure. For example, depending on the embodiment, certain acts, events, or functions of any of the algorithms described herein can be performed in a different sequence, can be added, merged, or left out all together (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines or computing systems that can function together.

The various illustrative logical blocks, modules, and algorithm steps described in connection with the embodiments disclosed herein can be implemented as electronic hardware, computer software, or combinations of both. To clearly illustrate this interchangeability of hardware and software, various illustrative components, blocks, modules, and steps have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described in connection with the embodiments disclosed herein can be implemented or performed by a machine, such as a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor can be a microprocessor, but in the alternative, the processor can be a controller, microcontroller, or state machine, combinations of the same, or the like. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor can also include primarily analog components. For example, any of the signal processing algorithms described herein can be implemented in analog circuitry. A computing environment can include any type of computer system, including, but not limited to, a computer system based on a microprocessor, a mainframe computer, a digital signal processor, a portable computing device, a personal organizer, a device controller, and a computational engine within an appliance, to name a few.

The steps of a method, process, or algorithm described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of non-transitory computer-readable storage medium, media, or physical computer storage known in the art. An exemplary storage medium can be coupled to the processor such that the processor can read information from, and write information to, the storage medium. In the alternative, the storage medium can be integral to the processor. The processor and the storage medium can reside in an ASIC. The ASIC can reside in a user terminal. In the alternative, the processor and the storage medium can reside as discrete components in a user terminal.

Conditional language used herein, such as, among others, “can,” “might,” “may,” “e.g.,” and the like, unless specifically stated otherwise, or otherwise understood within the context as used, is generally intended to convey that certain embodiments include, while other embodiments do not include, certain features, elements or states. Thus, such conditional language is not generally intended to imply that features, elements or states are in any way required for one or more embodiments or that one or more embodiments necessarily include logic for deciding, with or without author input or prompting, whether these features, elements or states are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, or Z,” unless specifically stated otherwise, is otherwise understood with the context as used in general to present that an item, term, etc., can be either X, Y, or Z, or any combination thereof (e.g., X, Y, or Z). Thus, such disjunctive language is not generally intended to, and should not, imply that certain embodiments require at least one of X, at least one of Y, or at least one of Z to each be present.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C.

While the above detailed description has shown, described, and pointed out novel features as applied to various embodiments, it will be understood that various omissions, substitutions, and changes in the form and details of the devices or algorithms illustrated can be made without departing from the spirit of the disclosure. As will be recognized, certain embodiments described herein can be embodied within a form that does not provide all of the features and benefits set forth herein, as some features can be used or practiced separately from others. It should be emphasized that many variations and modifications can be made to the above-described embodiments, the elements of which are to be understood as being among other acceptable examples. All such modifications and variations are intended to be included herein within the scope of this disclosure and protected by the following claims.

What is claimed is:

1. A solar power system for use with automotive vehicles, the solar power system comprising:
at least one solar panel package disposed on a vehicle surface, the solar panel package configured to adhere to a vehicle surface by an adhesive material, wherein the at least one solar panel package comprises:
a support layer comprising a shock absorption layer configured to reduce vibration from vertical movements of the vehicle surface;
a conductive layer disposed on the support layer, said conductive layer configured to provide rigidity to the at least one solar panel package; and
a solar cell layer disposed above the conductive layer, said solar cell layer configured to capture photons and convert into electricity,
wherein the conductive layer is further configured to reflect photons that passed through the solar cell layer, thereby not initially captured, back into the solar cell layer; and
an encapsulating layer configured to cover at least the solar cell layer, the encapsulating layer comprising a material configured to allow transmission of light and protect the solar cell layer from impact damage.

2. The solar power system of any of the above claims wherein the at least one solar panel package comprises twenty four solar panel packages.

3. The solar power system of any of the above claims, wherein the at least one solar power package is configured to cover an area of the vehicle surface sufficient to supply power for a refrigeration unit associated with the vehicle.

4. The solar power system of any of the above claims wherein the adhesive material comprises a bonding adhesive.

5. The solar power system of any of the above claims, wherein the support layer comprises a fiberglass material.

6. The solar power system of any of the above claims, wherein the shock absorption layer comprises foam core.

7. The solar cell system of any of the above claims, wherein the shock absorption layer comprises a honeycomb shaped material.

8. The solar cell system of any of the above claims, wherein the conductive layer comprises a carbon fiber material impregnated with resin.

9. The solar cell system any of the above claims wherein the encapsulating layer comprises a transparent laminate.

10. The solar cell system any of the above claims, wherein the encapsulating comprises an ink layer configured to hide electrical components of the solar cell layer.

11. A method of configuring an automotive vehicle to include a solar power system, the method comprising:
providing an adhesive layer to a vehicle surface;
providing at least one solar panel package to the vehicle surface, said at least one solar panel package comprising:
a support layer comprising a shock absorption layer configured to reduce vibration from vertical movements of the vehicle surface;
a conductive layer disposed on the support layer, said conductive layer configured to provide rigidity to the at least one solar panel package; and
a solar cell layer disposed above the conductive layer, said solar cell layer configured to capture photons and convert into electricity,
wherein the conductive layer is further configured to reflect photons that passed through the solar cell layer, thereby not initially captured, back into the solar cell layer; and
applying an encapsulating layer configured to cover at least the solar cell layer, the encapsulating layer comprising a material configured to allow transmission of light and protect the solar cell layer from impact damage.

12. The method of any of the above claims, wherein the at least one solar panel package comprises twenty four solar panel packages.

13. The method of any of the above claims, wherein the at least one solar panel package is configured to cover an area of the vehicle surface sufficient to supply power for a refrigeration unit associated with the vehicle.

14. The method of any of the above claims, wherein the adhesive layer comprises an adhesive material.

15. The method of any of the above claims, wherein the adhesive material comprises a bonding adhesive.

16. The method of any of the above claims, wherein the support layer comprises a fiberglass material.

17. The method of any of the above claims, wherein the shock absorbing layer comprises a shock absorption material.

18. The method of any of the above claims, wherein the shock absorption material comprises foam core.

19. The method of any of the above claims, wherein the shock absorption layer comprises a honeycomb shaped structure.

20. The method of any of the above claims, wherein the conductive layer comprises a carbon fiber material impregnated with resin.

21. The method of any of the above claims, wherein the encapsulating layer comprises a transparent laminate.

22. The method of any of the above claims, wherein the encapsulating comprises an ink layer configured to hide electrical components of the solar cell layer.

23. The method of any of the above claims further comprising electrically connecting the solar panel package to electronic components associated with the vehicle.

24. The method of any of the above claims further comprising electrically connecting the solar panel package to electronic components associated with the refrigeration system.

25. A method of manufacturing a solar panel package, the method comprising:
providing a shock absorption layer to a reinforcement material;
providing a conductive material to the shock absorption layer; and
providing a solar cell layer to the conductive material.

26. The method of any of the above claims, wherein the reinforcement material comprises fiberglass impregnated with resin.

27. The method of any of the above claims, wherein the shock absorption layer comprises foam core.

28. The method of any of the above claims, wherein the shock absorption layer comprises a honeycomb shaped structure.

29. The method of any of the above claims, wherein the conductive material comprises a carbon fiber material impregnated with resin.

30. The method of any of the above claims, wherein the conductive material is configured to reflect photons that passed through the solar cell layer, thereby not initially captured, back into the solar cell layer.

31. The method of any of the above claims wherein the conductive material is configured to provide rigidity to the at least one solar panel package.

32. A method of disposing a solar power system on a truck trailer, the method comprising:
providing an adhesive layer to a first surface of the truck trailer;
providing at least one solar panel package to the surface of the truck trailer, wherein the adhesive layer is disposed between the surface and the solar panel package;
providing an encapsulating layer over the solar panel package, the encapsulating layer comprising a material configured to allow transmission of light and protect the solar cell layer from impact damage;
attaching one or more power control components to a second surface of the truck trailer behind a weather resistant barrier; and
electrically connecting the one or more power control components to the at least one solar panel package, a power supply associated with the truck trailer, a display, external power supply, or a battery system configured to store power produced by the solar panel package.

33. The method of claim 32, wherein electrically connecting the one or more power control components comprises:
laying one or more power cables along one or more surfaces of the trailer;
feeding the one or more power cables through an electrical feed through connector associated with the weather resistant barrier; and
connecting the one or more power cables with the at least one solar panel package, a power supply associated with the truck trailer, a display, an external power supply, or a battery system configured to store power produced by the solar panel package.

34. The method of claim 32, wherein the at least one solar panel package comprises:
a support layer comprising a shock absorption layer configured to reduce vibration from vertical movements of the vehicle surface;
a reinforcing layer disposed on the support layer, said reinforcing layer configured to provide rigidity to the at least one solar panel package; and
a solar cell layer disposed above the reinforcing layer, said solar cell layer configured to capture photons and convert into electricity.

35. A method of disposing a solar power system on a truck trailer, the method comprising:
calculating a power need for the truck trailer;
calculating a threshold surface area to meet the power need;
determining an suitable surface area for one or more solar panel packages on the truck trailer;
applying the one or more solar panel packages on the truck trailer;
attaching one or more movable panels comprising one or more additional solar panel packages to the truck trailer if the suitable surface area is less than the threshold surface area;
attaching one or more power control components to a surface of the truck trailer behind a weather resistant barrier; and
electrically connecting the one or more power control components to at least one of the one or more solar panel packages, a power supply associated with the truck trailer, a display, an external power supply, or a battery system configured to store power.

36. The method of claim 35, wherein electrically connecting the one or more power control components comprises:
laying one or more power cables along one or more surfaces of the trailer;
feeding the one or more power cables through an electrical feed through connector associated with the weather resistant barrier; and
connecting the one or more power cables with at least one of the one or more solar panel packages, a power supply associated with the truck trailer, a display, external power supply, or a battery system configured to store power produced by the solar panel package.

37. The method of claim 35, wherein the one or more solar panel packages comprise:
a support layer comprising a shock absorption layer configured to reduce vibration from vertical movements of the vehicle surface;
a reinforcing layer disposed on the support layer, said reinforcing layer configured to provide rigidity to the at least one solar panel package; and
a solar cell layer disposed above the reinforcing layer, said solar cell layer configured to capture photons and convert into electricity.

38. A solar power system for use with a trailer, the solar power system comprising:
at least one solar panel package;
a first securing portion disposed onto a vertical surface of the trailer, the first support portion configured to secure at least a portion of the solar panel package during transit of the trailer;
at least one hinge configured to allow the at least one solar panel package to pivot around an axis of the solar panel package; and
a moving component configured to orient the at least one solar panel package into a position associated with improved sun exposure.

39. The solar power system of claim 38, wherein the at least one solar panel package comprises:
a support layer comprising a shock absorption layer configured to reduce vibration from vertical movements of the vehicle surface;
a reinforcing layer disposed on the support layer, said reinforcing layer configured to provide rigidity to the at least one solar panel package; and
a solar cell layer disposed above the reinforcing layer, said solar cell layer configured to capture photons and convert into electricity.
